(19) United States
(12) Patent Application Publication
(10) Pub. No.: US 2013/0285727 A1
(43) Pub. Date: Oct. 31, 2013

(54) OCTAL CLOCK PHASE INTERPOLATOR ARCHITECTURE

(71) Applicant: Texas Instruments Incorporated, Dallas, TX (US)

(72) Inventors: Andrew Pickering, Warwickshire (GB); Vipul Raithatha, Northampton (GB); Peter Hunt, Northamptonshire (GB)

(21) Appl. No.: 13/755,782

(22) Filed: Jan. 31, 2013

(30) Foreign Application Priority Data
Jan. 31, 2012 (GB) 1201611.9

(51) Int. Cl. H03K 5/15

(52) U.S. Cl. CPC H03K 5/15
USPC 327/254

(57) ABSTRACT

The present invention provides an apparatus and method of generating a set of 8 clock signals nominally spaced at equal 45° intervals by phase interpolation from a set of 4 quadrature reference clocks. The scheme is useful for clock generation for data capture in an oversampled clock/data recovery (CDR) system where the frequency of data sampling is twice that of the frequency of reference clock edges.

### FIELD OF THE INVENTION

This application claims priority under 35 USC §119(e)(1) of European Application Number GB 1201611.9, filed on Jan. 31, 2012.

The present invention relates to phase interpolators, and more particularly to an octal clock phase interpolator architecture.

### BACKGROUND OF THE INVENTION

A known interpolator-based over-sampled clock/data recovery (CDR) scheme is disclosed in the Applicant's prior patent no. GB2415101. In this scheme a set of four quadrature clocks are rotated to generate a set of four aligned clocks with which to capture samples from the serial data stream.

However, there is a need for an octal clock CDR phase interpolator architecture which the known prior scheme does not address.

### SUMMARY OF THE INVENTION

Accordingly, the present invention provides an apparatus and method of generating a set of 8 clock signals nominally spaced at equal 45° intervals by phase interpolation from a set of 4 quadrature reference clocks. The scheme is useful for clock generation for data capture in an oversampled clock/data recovery (CDR) system where the frequency of data sampling is twice that of the frequency of reference clock edges.

The proposed architecture of the present invention takes advantage of the re-use of just two basic building blocks to minimise design time and support.

According to a first aspect of the invention there is provided a clock phase generating means for generating a set of eight clock phases for a clock/data recovery application, comprising: a rotating first stage interpolator; and a pair of fixed-phase second stage interpolators; wherein the rotating first stage interpolator is coupled to the pair of fixed-phase second stage interpolators to generate two interleaved sets of quadrature clocks.

Preferably, the order of bias signals to one of said second stage interpolators is reversed causing its output clocks to be rotated by 22.5° in the opposite direction to that of said other one of the second stage interpolators, thereby establishing a 45° phase shift between the first and second interpolator clock outputs.

According to a second aspect of the invention there is provided an octal clock phase interpolator comprising the clock phase generating means of the first aspect.

Further embodiments of the invention are as set forth in the accompanying claims.

Examples of the invention will now be described with reference to the accompanying drawings of which:

### BRIEF DESCRIPTION OF THE DRAWINGS

FIG. 1 shows representative waveforms for a typical interpolator-based over-sampled clock/data recovery scheme;

FIG. 2 shows representative waveforms for an interpolator-based over-sampled clock/data recovery scheme where the data rate is 2× higher than that shown in FIG. 1;

FIG. 3 shows a generic structure of a 4-quadrant phase interpolator;

FIG. 4 shows an interpolation block using two of the circuits of FIG. 3 in parallel which share the same bias controls (VB0 . . . VB3) but with the clock inputs to the second rotated by 90° with respect to the first;

FIGS. 5A and 5B show the structure and operation of a bias generator; and

FIG. 6 shows a scheme for generating octal data recovery clocks in accordance with a preferred embodiment of the present invention.

### DESCRIPTION OF SPECIFIC EMBODIMENTS OF THE INVENTION

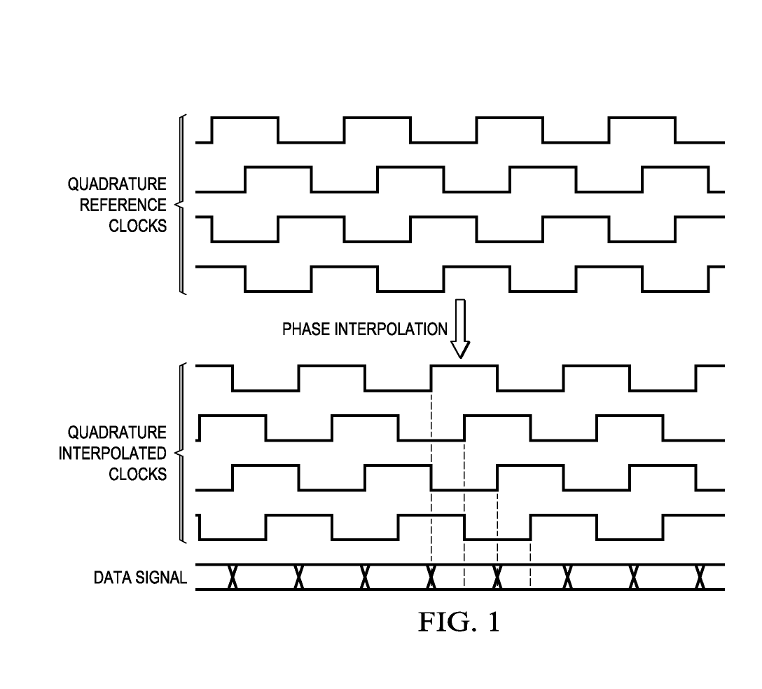

Representative waveforms for a prior interpolator-based over-sampled clock/data recovery scheme as disclosed in the Applicant's patent no. GB2415101 are shown in FIG. 1. In this scheme a set of four quadrature clocks are rotated to generate a set of four aligned clocks with which to capture samples from the serial data stream.

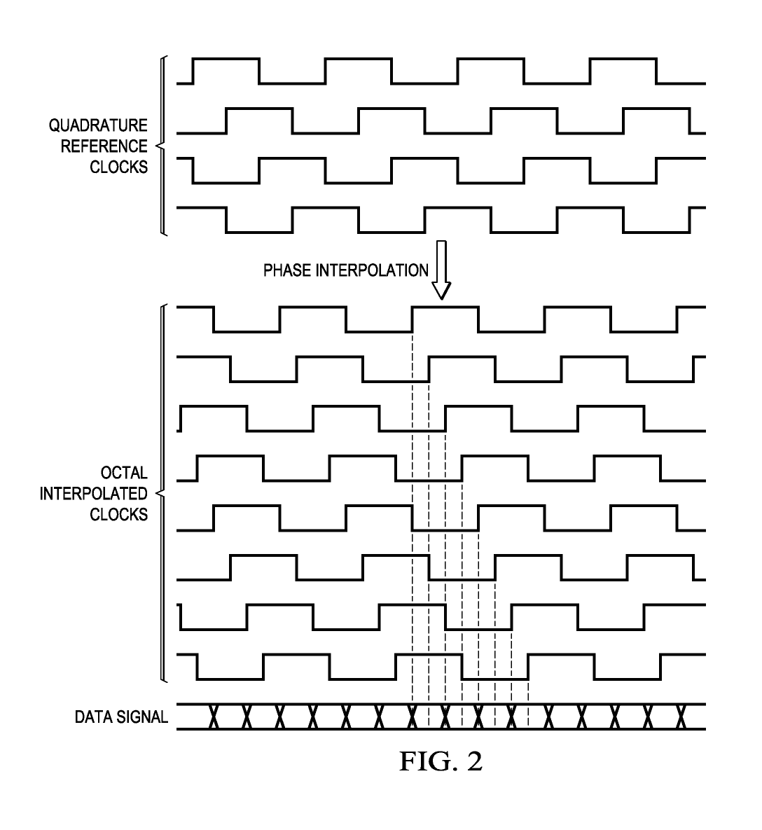

However the present invention addresses the case where the data rate is 2× higher than that shown in FIG. 1 and consequently demands a higher granularity of data sampling as shown in FIG. 2.

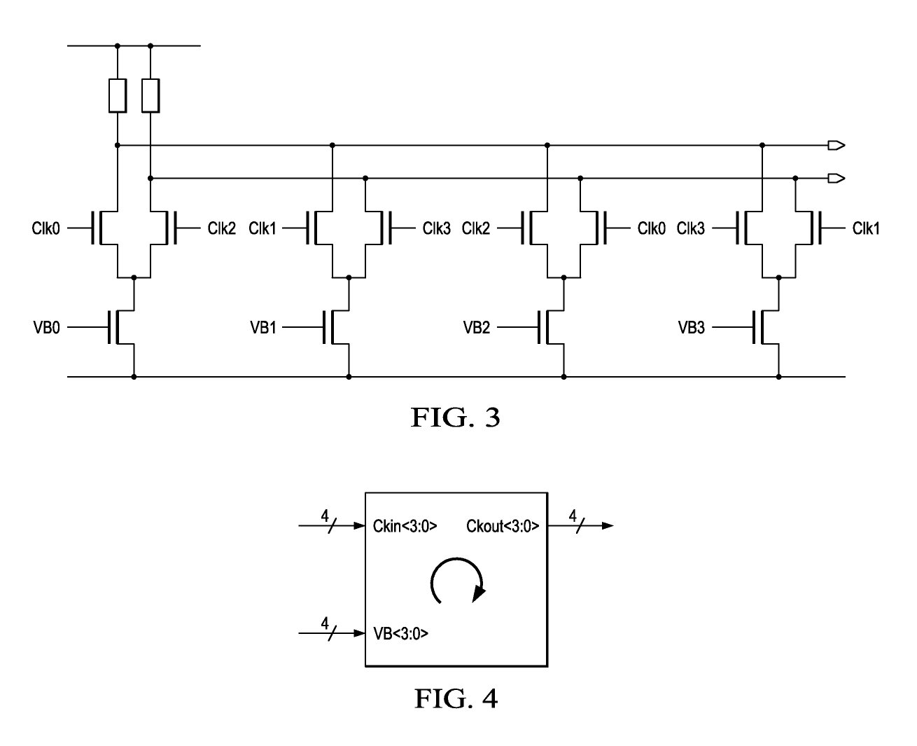

The generic structure of a 4-quadrant phase interpolator according to the Applicant's GB patent no. GB2415101 is shown in FIG. 3 and consists of a set of 4 differential amplifiers driven by quadrature clocks Clk0 & Clk1 and their complements C1k2 & C1k3 (i.e. 4 quadrature phases in total). The four differential amplifiers effectively operate at 90° intervals and each is connected to a current source device whose bias voltage is controlled in order to adjust the phase of the outgoing clock to the desired alignment.

The differential output signals in FIG. 3 are each amplified back up to full rail-to-rail swing signals to produce a pair of complementary CMOS clock signals.

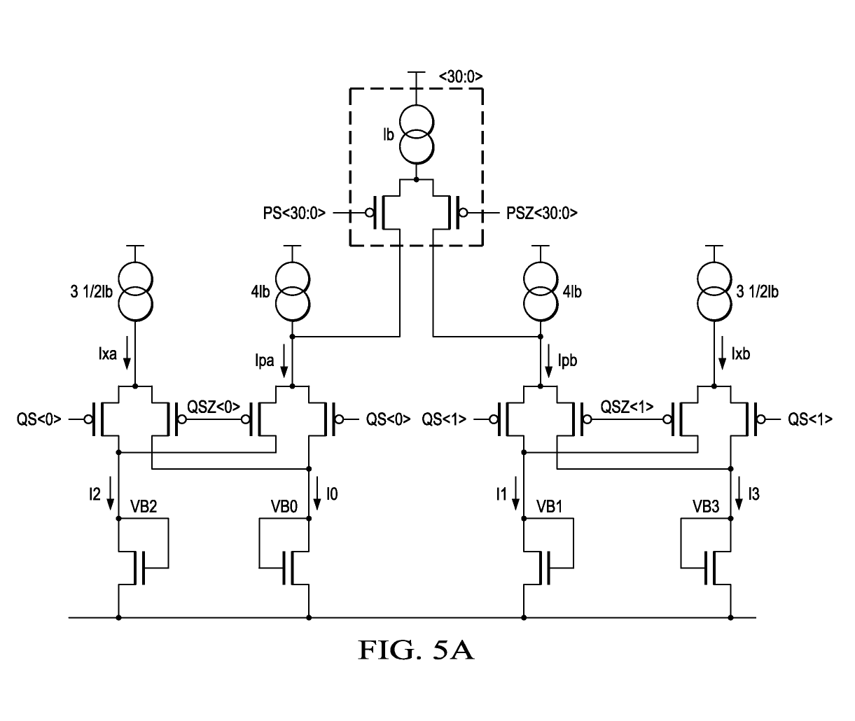

By using two of these circuits in parallel which share the same bias controls (VB0 . . . VB3) but with the clock inputs to the second rotated by 90° with respect to the first, a unit block is constructed which takes in 4 quadrature reference clocks and outputs 4 quadrature clocks of the same frequency but whose output phases may all be rotated (relative to the inputs) under control of the applied bias voltages. The symbol for such an interpolation block is shown in FIG. 4.

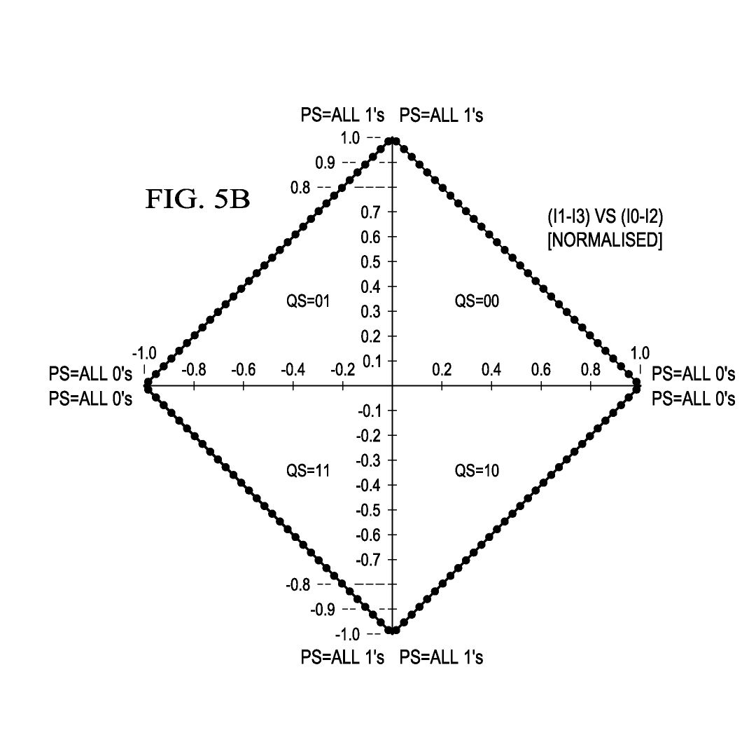

As described above, the phase of the output signal is controlled by the 4 bias voltages applied to each of the 4 differential pairs in the phase interpolator bridge. One such apparatus for achieving this is described in the Applicant's GB patent no. GB 2415100, and consists of an array of differentially switched current sources controlled using a thermometer code (PS<30:0> and complement PSZ<30:0>) to adjust the phase within a quadrant in conjunction with a 2-bit quadrant select code (QS<1:0> and complement QSZ<1:0>) to select the currently active quadrant. One possible embodiment of this bias generator is illustrated in FIGS. 5A and 5B.

### Octal Clock Generation

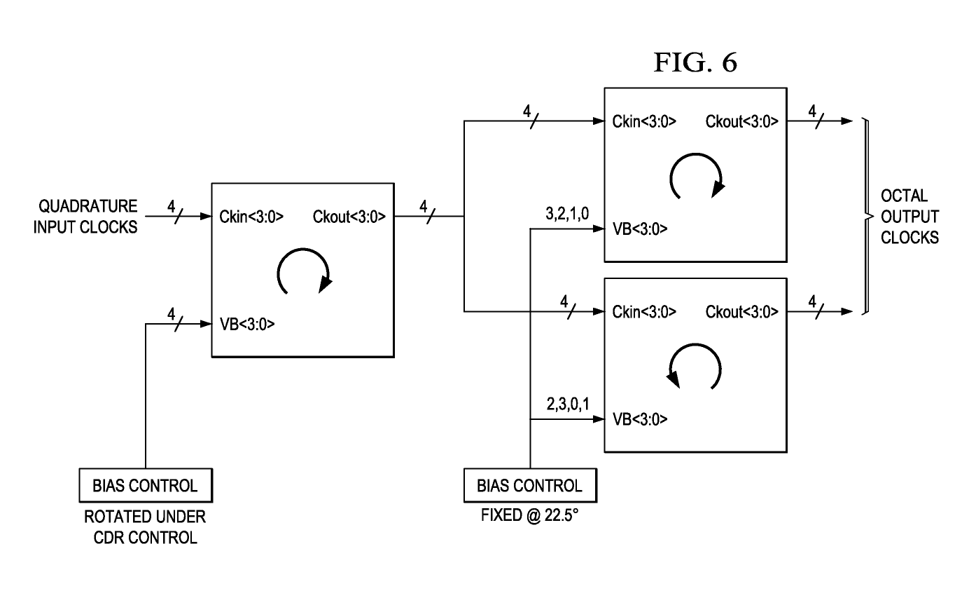

The inventors have realised a solution for generating the octal data recovery clocks according to the present invention as shown in FIG. 6. The first bias control block is controlled by the CDR loop to rotate the four quadrature input clocks to provide four further quadrature clocks with the required phase. This would only have been an adequate solution for the CDR scheme at half the data rate shown in FIG. 1. However, a second pair of phase interpolators is then used to rotate the clocks nominally by 22.5°, but crucially the order of bias signals to one of these interpolators is reversed. This causes its output clocks to be rotated by 22.5° in the opposite direction, thus establishing a 45° phase shift between the first and second interpolator clock outputs. The combined outputs from the two second stage interpolator blocks thus provide all 8 clocks required to implement the data capture scheme shown in FIG. 2.

Although the second stage bias control is nominally fixed, it may be desirable to optionally include some means of adjustment of its phase setting to adjust the timings between the clocks output from the two 2nd stage interpolators. Such adjustment will rotate the interpolators in opposite directions, thereby changing the timing between the two interleaved sets of clock phases.

1. A clock phase generating circuit for generating a set of eight clock phases for a clock/data recovery application, comprising:
a rotating first stage interpolator; and
a pair of fixed-phase second stage interpolators;
wherein the rotating first stage interpolator is coupled to the pair of fixed-phase second stage interpolators to generate two interleaved sets of quadrature clocks.

2. A clock phase generating circuit as according to claim 1, wherein the order of bias signals to one of said second stage interpolators is reversed causing its output clocks to be rotated by 22.5° in the opposite direction to that of said other one of the second stage interpolators, thereby establishing a 45° phase shift between the first and second interpolator clock outputs.

3. A clock phase generating circuit as in claim 1, further comprising phase setting adjustment means for rotating the phase of the second stage interpolators in opposite directions.

4. A clock phase generating circuit as in claim 1, further comprising bias control adjustment means for adjustment of the phase setting of said second stage interpolators to adjust the timings between the clocks output from the two second stage interpolators.

5. An octal clock phase interpolator comprising:
a clock phase generating means for generating a set of eight clock phases for a clock/data recovery application, comprising:
a rotating first stage interpolator; and
a pair of fixed-phase second stage interpolators;
wherein the rotating first stage interpolator is coupled to the pair of fixed-phase second stage interpolators to generate two interleaved sets of quadrature clocks.

6. A receiver-side circuit comprising:
an octal clock phase interpolator comprising:
a clock phase generating means for generating a set of eight clock phases for a clock/data recovery application, comprising:
a rotating first stage interpolator; and
a pair of fixed-phase second stage interpolators;
wherein the rotating first stage interpolator is coupled to the pair of fixed-phase second stage interpolators to generate two interleaved sets of quadrature clocks.

7. A clock phase generating circuit for generating a set of eight clock phases for a clock/data recovery application, comprising:
a rotating first stage interpolator;
a pair of fixed-phase second stage interpolators;
wherein the rotating first stage interpolator is coupled to the pair of fixed-phase second stage interpolators to generate two interleaved sets of quadrature clocks; and
bias control adjustment means for adjustment of the phase setting of said second stage interpolators to adjust the timings between the clocks output from the two second stage interpolators.

8. An octal clock phase interpolator comprising:
a clock phase generating means for generating a set of eight clock phases for a clock/data recovery application, comprising:
a rotating first stage interpolator; and
a pair of fixed-phase second stage interpolators;
wherein the rotating first stage interpolator is coupled to the pair of fixed-phase second stage interpolators to generate two interleaved sets of quadrature clocks; and
wherein the order of bias signals to one of said second stage interpolators is reversed causing its output clocks to be rotated by 22.5° in the opposite direction to that of said other one of the second stage interpolators, thereby establishing a 45° phase shift between the first and second interpolator clock outputs.

9. A receiver-side circuit comprising:
an octal clock phase interpolator comprising:
a clock phase generating means for generating a set of eight clock phases for a clock/data recovery application, comprising:
a rotating first stage interpolator; and
a pair of fixed-phase second stage interpolators;
wherein the rotating first stage interpolator is coupled to the pair of fixed-phase second stage interpolators to generate two interleaved sets of quadrature clocks; and
wherein the order of bias signals to one of said second stage interpolators is reversed causing its output clocks to be rotated by 22.5° in the opposite direction to that of said other one of the second stage interpolators, thereby establishing a 45° phase shift between the first and second interpolator clock outputs.
